(19) United States
(12) Patent Application Publication
(10) Pub. No.: US 2009/0257535 A1
(43) Pub. Date: Oct. 15, 2009

(54) Method and Device for Compensating the Doppler Effect for a Digital Signal Receiver

(76) Inventors: Jean-Luc Robert, Betton (FR); Jean-Yves Le Naour, Pace (FR); Jean-Francois Pintos, Bourgbarre (FR)

Correspondence Address: Thomson Licensing LLC, P.O. Box 5312, Two Independence Way, PRINCETON, NJ, 08543-5312, US

(21) Appl. No.: 12/083,307

(22) PCT Filed: Oct. 16, 2006
(86) PCT No.: PCT/EP2006/067435

§ 371 Date: Apr. 9, 2008

(30) Foreign Application Priority Data
Oct. 18, 2005 (FR) 0553160

(51) Int. Cl. H03D 1/04

(52) U.S. Cl. 375/346

(57) ABSTRACT

The invention relates to a method of compensating the Doppler effect for a mobile receiver. This method consists in producing a phase-locked loop based on the signal to be demodulated to correct the frequency control of the tuner element and thus the drift due to the Doppler effect. The invention also relates to a receiver implementing this method.

The present invention relates to a digital signal receiver and, more particularly, to a method of compensating the Doppler effect, and to the associated device for processing a receive signal affected by a distortion due to the Doppler effect. It falls in particular within the scope of the implementation of the emergent DVB-H (Digital Video Broadcast Handheld) standard, the object of which is to enable digital television programmes to be received from mobile terminals.

The reception of digital television programmes in moving vehicles in an urban, suburban or rural environment is technically possible but requires powerful receivers in order to minimize the effects of propagation and, more particularly, the Doppler effect due to the speed which causes, among other things, a frequency shift on the channel.

The two-channel or four-channel antenna diversity solutions remain an effective means of combating these phenomena which cause unwanted breaks in reception. They require the implementation on the one hand of multiple antennas on a vehicle and a receiver provided with a number of complete receive subsystems, associated with the antennas, and on the other hand, a relatively costly processing system. It would also not be appropriate for battery-powered applications.
The DVB-T (Digital Video Broadcast Terrestrial) standard used for the transmission of programmes to mobile terminals has major limitations considering the modulation parameters to be selected. In practice, for an “8 k carriers and 64 QAM (Quadrature Amplitude Modulation)” type modulation, the reception limit appears at a mobile speed less than 50 km/h. It is therefore less robust when receiving when moving at high speeds, but offers a higher bit rate on a single channel, that is, it offers more programmes for the operators. For a “2 k carriers and QPSK (Quaternary Phase Shift Keying)” type modulation, the reception limit is located for vehicle speeds at around 400 km/h. The tolerance to the Doppler effect is therefore better but, at the cost of a lower channel bit rate.

The DVB-H system, through an intermediate choice of the number of carriers, in the event of the “4K carriers and COFDM (Combining Orthogonal Frequency Division Multiplex)” type, offers an acceptable trade-off in terms of channel bit rate and tolerance to Doppler effect.

Currently, digital processing functions incorporated in COFDM demodulator circuits make it possible to significantly improve the tolerance to Doppler effect, but this phenomenon nonetheless still remains present and detrimental to mobile reception.

The invention proposes to remedy this problem.

The invention consists of a method of compensating the Doppler effect for a mobile receiver on a signal affected by a distortion due to the Doppler effect. It consists in implementing, based on the signal to be demodulated, a phase-locked loop acting on the frequency control of the tuner element for selecting channels.

The step for implementing the phase-locked loop comprises:
a step for determining the image of the spurious modulation,
a step for defining the sign of the Doppler shift, and
a step for creating a control indication from the preceding data for adjusting the frequency control of the tuner element so that, before demodulation, the frequency drift generated by the Doppler effect can be corrected.

The method proposed by the invention thus makes it possible to very significantly improve the tolerance to Doppler spreading since it makes it possible to deliver a signal partly purged of the distortion inherent to this phenomenon. It provides a way of reinforcing the effectiveness of the demodulator and therefore, consequently, of the receiver.

The invention also relates to a digital data receiver comprising, upstream of the demodulator, a means of processing the intermediate-frequency signal to be demodulated to determine the image of the spurious modulation, a means for defining the sign of the Doppler shift, and a means for creating a tuner element frequency control indication, from the preceding data, for correcting, before modulation, the frequency drift generated by the Doppler effect.
According to a variant of the invention, the signal processing means comprise a delay frequency discriminator. Preferably, it is formed by a mixer driven on the RF input by the intermediate-frequency signal and on the LO input by the same signal affected by a delay T.
According to a variant of the invention, the means for creating a frequency control indication comprise a computation block for analysing the indication obtained from the discriminator and the sign of the Doppler shift.

The compensation device thus makes it possible to very significantly improve the tolerance to Doppler spreading since it delivers to the demodulator a signal already partially purged of the distortion inherent to this phenomenon. This demodulator, which itself comprises an integrated Doppler compensation digital processing circuit, thus makes it possible to largely eliminate the disturbances due to this Doppler effect.

The receiver according to the invention can be integrated in a macro-module, which offers the advantage of enabling it to be inserted in mobile terrestrial digital receivers.

The characteristics and advantages of the invention mentioned above, and others, will become more clearly apparent from reading the following description, given in conjunction with the appended drawings, in which:

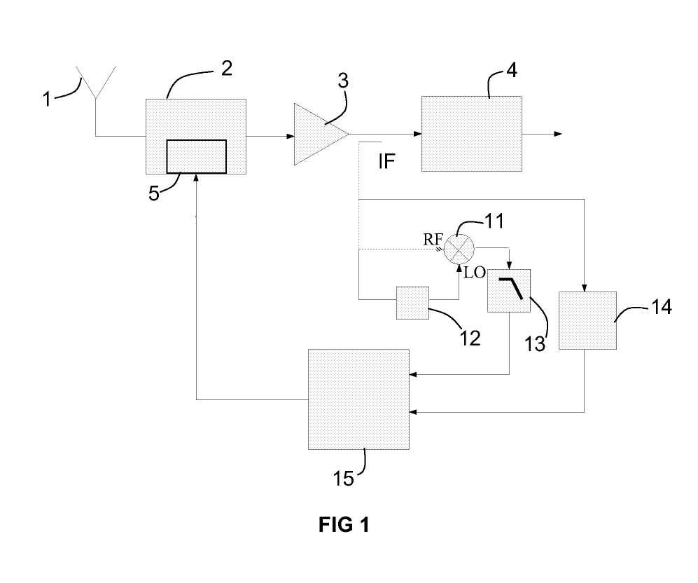

FIG. 1 represents an exemplary embodiment of the device according to the invention.

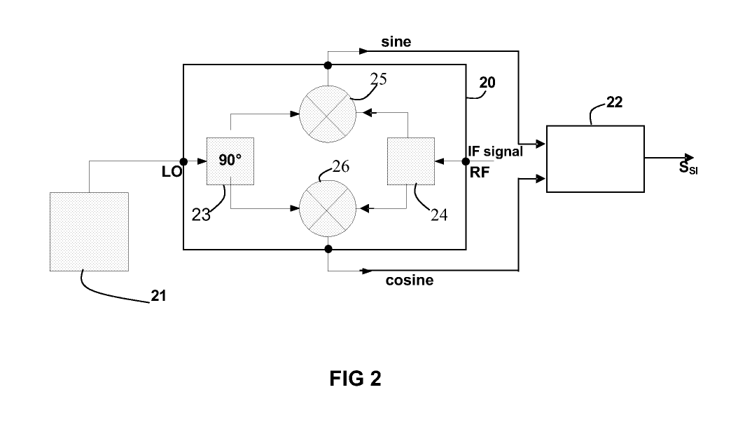

FIG. 2 represents an exemplary embodiment of the Doppler sign detection block.

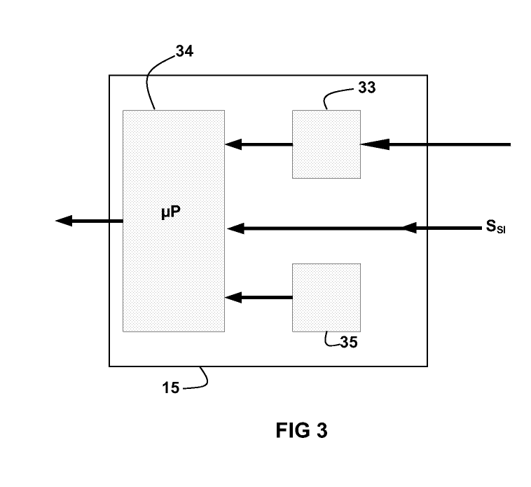

FIG. 3 represents an exemplary architecture of the Doppler processing block.

The principle of the device or the method according to the invention is based on the analysis of the Doppler phenomenon explained below:

If the signal received by the antenna 1 of the receiver is affected by an echo but without Doppler shift, then the echo of this OFDM-modulated signal t of frequency ωₘ and of amplitude a, has an amplitude b and delay T. The resultant signal seen by the receiver at the instant t is:

R=a sin(ωₘt)+b sin ωₘ(t+.T.)

The amplitude of such a signal takes the form:

A#√(a²+b²)+b cos (ω.ₘT.)

The amplitude is a function of the frequency of the carrier with maxima for ωₘT=2TT.

If the receiver is mobile, the echo b is then affected by the Doppler effect and subjected to a frequency shift (Δfₘ), the resultant signal seen by the receiver at the instant t then becomes:

R=a sin(ωₘt)+b sin(ωₘ+Δωₘ)(t+T) with Δωₘ=2TT/Δfₘ

The OFDM signal then has an amplitude of the form:

A#√(a²+b²)+2b cos(ΔωₘT)

The maxima correspond to the Doppler frequency (Δωₘ=2TT)

The result is that the carriers of the OFDM signal for a given received channel are affected by a spurious modulation in pace with the Doppler frequency.

The method according to the invention then consists in determining the image of the spurious modulation applied by the Doppler effect and the sign of the Doppler shift Δωₘ, then in processing these two data items, so as to form a control signal to adjust the frequency of the tuner.

An exemplary embodiment of the device according to the invention, associated with the method, is represented by FIG. 1. The receiver, provided in the exemplary embodiment with a single antenna 1, comprises a conventional receive subsystem formed by the following basic elements: an antenna 1, a tuner element 2, an amplifier 3 and a demodulator 4. In the context of antenna-diversity reception, the reception can also take place via several antennas, the received signals then being recombined according to different and well known methods. The tuner element 2 is, in the example of FIG. 1, a tuner with PLL frequency synthesizer.

The signal received by the antenna 1 is applied to the tuner 2 which selects a receive channel. The intermediate-frequency signal (for example 36 MHz) is then applied to the amplifier 3 and then to the demodulator 4 thus delivering the demodulated signal. In the present case, it is a COFDM demodulator, but any other demodulator corresponding to the modulation of the received signal can be envisaged. This demodulator incorporates a Doppler correction circuit enabling a partial compensation of the Doppler effect.

According to the invention, a compensation of the Doppler effect is provided by a circuit sampling the intermediate-frequency IF signal upstream of the demodulator 4 and thus makes it possible to apply, by a phase-locked loop, on the tuner element, an adjustment of the channel selection frequency. This IF signal input to this compensation circuit is sampled by a coupler, not shown in FIG. 1, and this compensation circuit will deliver to the frequency synthesizer 5 of the tuner element the signal necessary to correct the selection frequency of the receive channel. In the example described, it is a tuner element with fractional-type synthesizer for controlling the channel selection.

The input signal of the compensation circuit is an intermediate-frequency IF signal which is applied to a frequency discriminator formed by a mixer 11 and a delay circuit 12, then filtered by a low-pass filter 13. The intermediate-frequency signal is applied to the RF input of the mixer and this same signal, affected by the delay T, introduced by the delay circuit 12, is applied to the LO input. This circuit therefore constitutes a delay-line demodulator known in the state of the art. It can be demonstrated that, for example, for a delay of TT/2, the output indication from the demodulator is a voltage proportional to the frequency modulation of the incoming signal. The result is that the indication obtained from this discriminator is, after filtering by the low-pass filter 13, the image of the spurious modulation caused by the Doppler effect and therefore represents the Doppler shift.

By applying this OFDM signal at intermediate frequency affected by the distortion added by the Doppler effect on the frequency discriminator formed by the mixer 11 and the delay element 12, the result is a signal for which the frequency modulation indication (Doppler fault) is contained in the frequency of the signal, after filtering. This signal therefore represents the image of the spurious modulation caused by the Doppler effect.

A second block 14 is responsible for determining the sign of the Doppler shift from the intermediate-frequency signal. FIG. 2 is an exemplary representation of this block and will be described below.

The two Doppler shift and sign indications are then sent to a processing block 15 managed by microcontroller charged with creating a new control indication to correct the adjustment of the tuner channel selection frequency. FIG. 3 is an exemplary representation of this block and will be described later.

Since the Doppler shift at its maximum is of the order of a few hundred Hz, the frequency synthesizer 5 of the tuner element 2 will in this case be implemented by a “Fractional N” type phase-locked loop providing an accuracy of about 1 Hz.

The possibility of integrating all these circuits within a macro-module thus allows this data processing circuit to be inserted into mobile terrestrial digital receivers.

FIG. 2 represents an exemplary implementation of the Doppler sign detection block 14.

This block comprises, as main element, a demodulator 20. A reference signal created by a digital synthesizer 21 is applied to the LO input of the demodulator 20. A circuit 23, phase-shifter and coupler, will be used to send the signal phase-shifted by 90° on one of its outputs, whereas it will be sent without phase shift on the other output. These two signals are respectively applied to the LO inputs of two mixers 25 and 26. The intermediate-frequency IF signal, sampled upstream of the demodulator (see FIG. 1) is applied to the RF input of the demodulator 20. This signal is applied via a coupler to each of the two inputs of the mixers 25 and 26 which deliver on their respective outputs a sinusoidal signal sin (ω_{D}+t) and cosinusoidal signal cos (ω_{D}+t) representing a value of the angular offset WD corresponding to the frequency shift f_{D}. The demodulator 20 is thus used in this case as a phase detector. A signal processing circuit 22 is linked to the demodulator 20. It receives on its inputs, the sine and cosine values delivered by the demodulator circuit and thus sends on its output a signal S _{SI} representative of the sign of the Doppler shift. It therefore makes it possible to determine if the frequency shift due to the Doppler effect is a shift leading to an increase or a decrease in the selected tuner frequency.

FIG. 3 represents an exemplary architecture of the Doppler processing block 15 of FIG. 1. This processing block 15 comprises an analysis circuit 34, for example a microprocessor. It receives, on one of its inputs, a signal obtained from the ADC (Analogue-Digital Converter) circuit 33 which converts the analogue signal corresponding to the image of the spurious modulation by Doppler effect obtained from the filter 13 into a digital signal. On the other input, it receives the signal S _{SI} representative of the sign of the Doppler shift. A reference memory 35 is associated with this analysis circuit. The references stored by this memory 35 are used to assign to the various values of the digital signal the corresponding values used to control the PLL synthesizer of the tuner element 2 which compensates the frequency difference due to the Doppler effect.

Other variants of the invention are possible. The examples described previously show a reception of the COFDM-modulated signal. Other modulations can be envisaged.

The examples described above show a circuit receiving the intermediate-frequency signal upstream of the demodulator. Any signal, affected by the disturbances of the Doppler effect, can be sampled upstream of the demodulator, at the amplifier or at other levels to control this phase-locked loop.

1. Method of compensating the Doppler effect on a signal affected by a distortion due to the Doppler effect in a mobile receiver by the implementation of a phase-locked loop acting on the frequency control of the tuner element for selecting channels, based on the signal to be demodulated, wherein it comprises:
a step for determining a signal corresponding to the image of the spurious modulation,
a step for defining a signal corresponding to the sign of the Doppler shift, and
a step for creating a tuner element (2) frequency correction data from the preceding signals.

2. Digital data receiver comprising at least one receive subsystem, associated with at least one antenna, and also comprising a tuner and a demodulator, wherein it comprises, upstream of the demodulator,
means of processing the intermediate-frequency signal to be demodulated to determine a signal corresponding to the image of the spurious modulation,
means for defining a signal corresponding to the sign of the Doppler shift, and
means for creating, from the preceding signals, a tuner element frequency control data for correcting the frequency drift generated by the Doppler effect.

3. Receiver according to claim 2, wherein the digital signal processing means comprise a delay frequency discriminator and a low-pass filter delivering a signal representing the image of the spurious modulation.

4. Receiver according to claim 3, wherein the frequency discriminator comprises a mixer driven on the RF input by the intermediate-frequency digital signal and on the LO input by the same signal affected by a delay.

5. Receiver according to claim 2, wherein the means for creating a frequency control data comprise a computation block for analysing the indication obtained from the discriminator and the sign of the Doppler shift.

6. Receiver according to claim 2, wherein the intermediate-frequency signal processing means, the means for defining the sign of the Doppler shift and the means for creating a frequency control indication can be integrated in a macro-module.
